(19) United States
(12) Patent Application Publication
(10) Pub. No.: US 2009/0294966 A1
(43) Pub. Date: Dec. 3, 2009

(54) CARBON NANOTUBES AS INTERCONNECTS IN INTEGRATED CIRCUITS AND METHOD OF FABRICATION

(75) Inventors: Jie Liu, Chapel Hill, NC (US); Anna Fontcuberta I Morral, Lausanne (CH)

Correspondence Address: UNIDYM Inc., 1244 Reamwood Avenue, Sunnyvale, CA, 94089, US

(73) Assignees: UNIDYM, INC., Menlo Park, CA (US); DUKE UNIVERSITY, Durham, NC (US)

(21) Appl. No.: 12/127,740

(22) Filed: May 27, 2008

(51) Int. Cl. H01L 23/52

(52) U.S. Cl. 257/746; 257/E23.141

(57) ABSTRACT

A method of making an electrode, such as an interconnect for a semiconductor device, includes forming aligned carbon nanotubes using dielectrophoresis.

### CROSS-REFERENCE TO RELATED PATENT APPLICATION

The present application claims benefit of U.S. provisional applications 60/739,929, filed Nov. 28, 2005, and 60/831,917, filed Jul. 20, 2006, both of which are incorporated herein by reference in their entirety.

### BACKGROUND OF THE INVENTION

Interconnects are metallic wires that carry electric power and signals in semiconductor and other solid state devices, such as a CMOS integrated circuit used for logic applications (i.e., microprocessor, etc.), or other transistor based arrays for memory applications (i.e., DRAM, EEPROM, etc.). As integrated circuits have continuously shrunk in size, the number and complexity of interconnects has dramatically increased. The result is a multilevel architecture of copper wiring isolated by low-dielectric constant isolating material, introduced to keep the capacitance (and therefore signal delay) of the wires low. Interconnects are typically divided into three groups: global, intermediate, and local. Global interconnects have the largest pitch and provide communication between large functional blocks, while local interconnects have the smallest pitch and are typically dedicated to interconnections within logic units. Intermediate interconnects have dimensions that are between those of global and local interconnects.

The speed of the electrical signals carried by interconnects is limited by the resistance of the wires and the capacitance between wires. In 1998, Intel led the transition from aluminum interconnects to copper interconnects to lower resistance and improve performance. Copper, however, is not a long term solution. As copper wires are made smaller, they will begin to have problems due to electromigration. Indeed, at ultra-small dimensions, copper atoms creep in the direction of current flow, leading to the formation of gaps within the wires and failures. This reliability problem can result in the loss of one or more connections, or even failure of the entire circuit.

In addition to performance failure, copper interconnects will also become increasingly difficult and costly to manufacture as feature sizes are reduced. Indeed, structural and electronic properties of copper wires intrinsically degrade for sizes on the tens of nm range. The increase of the ratio surface/volume of the wires means that the electron transport is much more perturbed by copper grain boundaries and wire surface roughness, reducing the wire conductivity and increasing the temperature of the circuit. Moreover, the down-scaling of Cu processing into sizes of tens of nm will encounter serious technical challenges, such as the fabrication of straight high aspect ratio trenches for the vias and the filling with high quality void-free Cu.

Carbon nanotubes have been proposed as a replacement for copper because they can carry large current densities and have lower resistance than copper at certain size scales. Metallic nanotubes have a current carrying capacity of one billion amps per square centimeter while copper wires burn out at one million amps per square centimeter. Theoretical predictions show that nanotubes in high aspect ratio structures such as vias should have lower resistance than copper wires. One recent model demonstrates that, when bundles of tens-of-micrometers long densely packed nanotubes with small contact resistances are used, nanotubes can be 80% faster than copper wires at the 22-nm node.

Several groups have attempted to develop processes for fabricating nanotube-based interconnects in integrated circuits. Thus far, direct chemical vapor deposition growth strategies have been used to directly synthesize the nanotubes in the right place on the chip. Metal catalyst islands are deposited at particular locations on the substrate, and hydrocarbon gases are introduced to catalyze growth of nanotubes. These direct growth approaches are limited by the quality of the materials synthesized and the high temperatures necessary for nanotube growth.

For example, US Published Application 2006/0091557 A1 describes a device having a wiring or a connection plug made of a mixture of a metal and carbon nanotubes buried in a wiring groove or a via hole made in an insulating film on a substrate. The method involves forming catalyst nanoparticles on an insulating base and then growing nanotubes on the nanoparticles using plasma-enhanced chemical vapor deposition, depositing a metal on the substrate on which the nanotubes are grown, and working the metal-nanotube combination into an interconnection.

In an alternative process, U.S. Published Application 2005/0218523 A1, incorporated herein by reference, discloses a method of making a composite copper-nanotube interconnect by mixing copper particles with nanotubes and forming the composite electrode. It is believed that this process forms an interconnect in which copper is the primary current carrier in the interconnect and the nanotubes provide a structural reinforcement role. Furthermore, it is believed that since the copper particles are mixed with the nanotubes before the composite is deposited, the carbon nanotubes in the interconnect are not aligned with each other.

As a result, there is a need for a CMOS-compatible, high volume manufacturing process for fabricating nanotube-based interconnects. Additionally, because local interconnects are more adversely affected by scattering-induced resistivity increases and non-scaling barriers, there is a need to develop a CMOS-compatible, high volume manufacturing process for fabricating local interconnects made of carbon nanotubes.

### SUMMARY

One embodiment of the invention provides a method for fabricating nanotube interconnects in an integrated circuit. Bundles of carbon nanotubes are prepared, and dielectrophoresis is used to deposit patterns of nanotube bundles with control over location, orientation, and density of nanotubes. Different processes are used to fabricate local horizontal interconnects and local vertical interconnects.

In another embodiment of the invention, individual nanotubes are prepared in a solvent, and dielectrophoresis is used to deposit individual nanotubes on the substrate. The individual nanotubes are deposited so that they form dense bundles of nanotubes on the chip with control over location and orientation of the nanotubes.

### BRIEF DESCRIPTION OF THE DRAWINGS

FIG. 1A is a schematic of an apparatus for making nanotube fibers using dielectrophoresis.

FIG. 1B is an SEM image of a nanotube fiber prepared using dielectrophoresis.

FIGS. 2, 3A, 3B, 5A, 5B, 5C, 6 and 8 are schematic side cross sectional views of steps in a method of depositing aligned nanotubes on preexisting templates using dielectrophoresis. FIG. 3A shows the side cross sectional view along line A-A in FIG. 4A. FIGS. 5A-5C show the side cross sectional view along line B-B in FIG. 4B.

FIGS. 4A, 4B and 7 are schematic three dimensional views of steps in a method of depositing aligned nanotubes on preexisting templates using dielectrophoresis.

FIG. 9 is an SEM image of a film of randomly oriented nanotubes.

### DETAILED DESCRIPTION OF THE EMBODIMENTS

Nanotube electrodes, such as interconnects in an integrated circuit, and methods of making the electrodes are provided. As used herein, the term “carbon nanotube” means a structure at least partially having a cylindrical structure mainly comprising carbon. The term includes multi-walled carbon nanotubes (MWNTs) (which include double-walled carbon nanotubes), single-walled carbon nanotubes (SWNTs), and other carbon nanostructures. Although single-walled carbon nanotubes are the material of choice, the methods described may be used with other types of nanotubes. The term “electrode” includes all electrical conductors which electrically connect features of solid state and other devices, such as interconnects, wires and contact electrodes which provide electron or hole injection into source or drain regions of a transistor. The electrode preferably has nanoscale dimensions along two out of its three dimensions (i.e., the electrode preferably has a microscale length).

The present inventors realized that an electrode may be fabricated by forming aligned carbon nanotubes using dielectrophoresis. Thus, metal catalyst islands used for CVD nanotube growth are not required. In one embodiment, the carbon nanotubes are preferably not interspersed with a filler material, such as copper or another filler. In this embodiment, whether the nanotubes are interspersed with a filler material or not, preferably the carbon nanotubes (rather than copper) comprise a primary current carrier of the electrode, such as an interconnect. This significantly improves the conductivity of the electrode compared to that of a copper interconnect. Furthermore, copper electromigration problems are avoided by using nanotubes instead of copper as the interconnect material. In another embodiment, the nanotubes are formed on a copper or aluminum electrode, such as an interconnect, and the metal portion of the electrode may comprise the primary current carrier of the electrode. The copper or other electrode metal in this embodiment has several functions, such as establishing a good electrical contact, reinforcing the mechanical properties of the electrode and helping the alignment of the nanotubes at the bottom of the vias and other openings in the dielectrophoresis process.

Dielectrophoresis involves controlled deposition of nanotubes from a solution or suspension. In this approach, nanotubes are synthesized, dispersed in solution or suspension, and treated. Dielectrophoresis involves applying an electric field, such as an alternating electric field, to apply a force to a polarizable object. Two electrodes in separate locations are used to trap and manipulate nanoscale materials. To deposit a nanotube electrode on a substrate located in a nanotube containing solution or suspension, a voltage (i.e., a potential) is applied between a conductive template on the substrate and a counter electrode located in a nanotube containing solution or suspension. This causes aligned nanotubes to deposit on the conductive template. The counter electrode is preferably not located on the same substrate as the template. However, if desired, the counter electrode may be located on the same substrate as the template, but with the counter electrode and template being located on different portions of the substrate.

### 1. First Embodiment—Nanotube Bundle Formation

The first embodiment of the invention provides a method for fabricating nanotube bundles in a solution or suspension followed by using the bundles to form an electrode, such as an interconnect for an integrated circuit. The bundles are deposited on the chip with control over location, orientation, and density of nanotubes.

First, suspended and separated carbon nanotubes are prepared in a solution or suspension. Nanotubes can be manufactured by chemical vapor deposition, arc discharge, laser ablation or other known methods. In a preferred method, chemical vapor deposition is used to synthesize high quality single-walled carbon nanotubes. A variety of different methods can then be used to purify the nanotubes. The nanotubes are then dispersed in a solvent. Examples of solvents include, but are not limited to, water, DMF and alcohols with or without surfactant. Sonication and/or shear mixing may be used to disperse nanotubes in the solvent. The nanotubes may then be treated to obtain highly metallic concentrations of nanotubes. Known methods for separating nanotubes by their electronic properties (i.e., separating semiconducting versus metallic nanotubes) include the use of DNA, long chain amines, dizonium salts, and bromine. DNA may also be used as a stabilizing media in the solution or suspension and may be used to separate the nanotubes into small bundles and individual nanotubes. Preferably, the nanotubes to be provided in the electrode comprise at least 90% metallic nanotubes after the separation step. The separated metallic nanotubes are then deposited into the electrode.

Bundles of aligned carbon nanotubes are then formed in the solvent before the nanotubes are placed on the chip. For example, the nanotube/solvent interaction can be controlled to form the bundles using dielectrophoresis or other bundle forming methods.

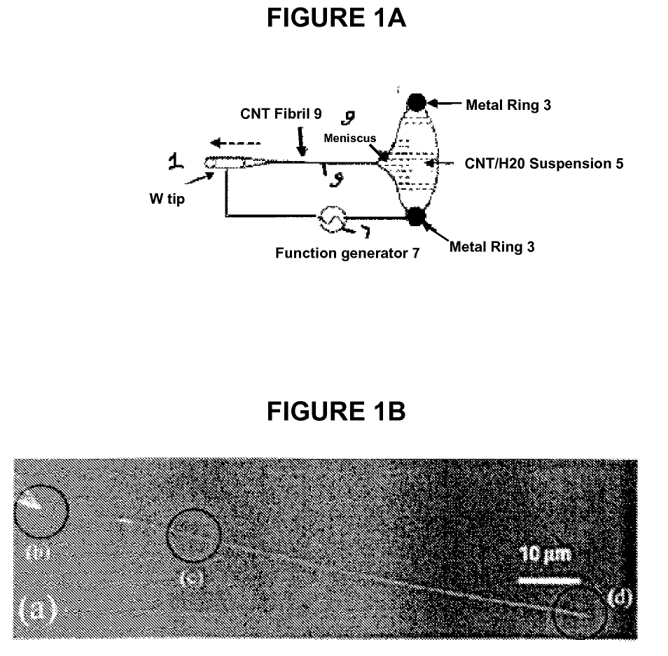

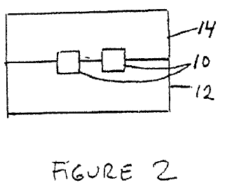

A method and apparatus for forming nanotube bundles in a solvent is illustrated in FIG. 1A. As shown in FIG. 1, an electrode 1, such as a tungsten tip or another electrode material, and a counter electrode 3, such as a metal ring, are provided in contact with a nanotube containing solution or suspension 5. A voltage source 7, such as a function generator, is used to establish an AC field between the electrodes 1 and 3. The AC field may comprise, for example, a voltage of 2-50 V, such as 10 V and a frequency of 1 to 10 MHz, such as 2 MHz. The electrode 1 is translated to contact the surface of the solution or suspension 5 and is then gradually withdrawn under the AC field to draw a nanotube bundle fibril 9 which is anchored to the electrode 1. FIG. 1B shows an SEM image of a SWNT fibril drawn from a SWNT-water suspension by the process shown in FIG. 1A. See Tang et. al., Adv. Mater. (2003) 15, No. 16, 1352, incorporated herein by reference.

Additionally, nanotube bundles can be annealed to improve the tube-tube interaction. Annealing may include heating the nanotube bundles in a furnace or passing a high current through the nanotube bundles. In another aspect of the first embodiment, contact between nanotubes in a bundle is enhanced through interaction with metals. Examples of metals include palladium and nickel. Upon annealing, these metals can diffuse through nanotube bundles to form metallic contact with most nanotubes in the bundle. The annealing may be conducted after the nanotube bundles are removed from the solution or suspension.

After bundles of densely packed nanotubes are formed, the bundles are placed over the substrate to form the electrode, such as an interconnect. The bundles may be placed over the substrate by using a second dielectrophoresis step or by using other nanotube deposition steps. The second dielectrophoresis step will be described below in more detail with respect to the third and fourth embodiments. Briefly, the nanotube bundles created by the first dielectrophoresis step or by other methods are provided into a suspension. The substrate is then placed into the suspension and the electrode is formed over the substrate by using the second dielectrophoresis step or another nanotube deposition method. The dielectrophoresis step(s) may be used to a create a nanotube electrode with control over location, orientation, and density of nanotubes, as will be described in more detail below.

### 2. Second Embodiment—Direct Nanotube Deposition

In a second embodiment of the invention, individual nanotubes are prepared in a solvent, and dielectrophoresis is used to deposit individual nanotubes over the substrate. The individual nanotubes are deposited so that they form bundles of nanotubes over the substrate, such as the semiconductor chip. Thus, rather than forming the bundles in the solution, the bundle is formed on the conductive template over the substrate (i.e., on the chip) from separated nanotubes in the solution. Dielectrophoresis can be used to make carbon nanotube bundles with diameters between 10-50 nm. The diameter of the bundles can be controlled and the length can be up to several centimeters, such as two to ten centimeters. In the second embodiment, only one dielectrophoresis step is needed to deposit the electrode, as will be described in more detail with respect to the third and fourth embodiments, below.

### 3. Third Embodiment—Formation of Horizontal Interconnects

While interconnects for integrated circuits, such as semiconductor memory or logic devices are described below, it should be understood that other types of electrodes for various solid state devices, such as display devices, may be formed as well.

The third embodiment of the invention provides a process for depositing bundles of nanotubes to form horizontal interconnects, such as local horizontal interconnects within logic units of semiconductor logic devices. The method of the first or the second embodiment may be used to form the interconnects.

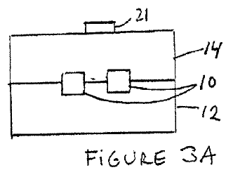

First, the semiconductor devices 10, such as transistors (i.e., field effect transistors, bipolar transistors, etc.), diodes and/or capacitors, etc., are formed in, on or over a substrate 12, such as a semiconductor (i.e., silicon, GaAs, etc.), insulating (glass, quartz, plastic, silicon on insulator, etc.,) or conductive substrate. Then, an interlayer insulating layer 14 is formed over the devices, as shown in FIG. 2.

Standard lithographic techniques are then used to form a conductive template pattern 21, such as a metal pattern over the substrate 12. The template may comprise, but is not limited to, palladium, nickel, or other metals that form ohmic-type (i.e., low resistance, non-Schottky) contacts with nanotubes.

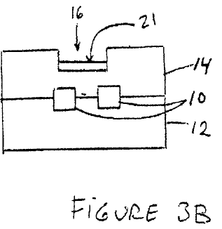

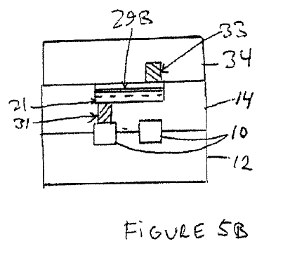

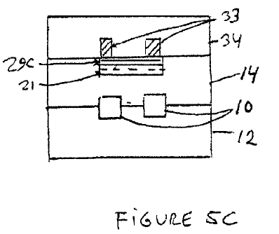

The template pattern 21 may be formed on the top surface of the interlayer insulating layer 14 or in a trench 16 in the interlayer insulating layer 14, as shown in FIGS. 3A and 3B, respectively. The template 21 may contact one or more metallization lines or plugs (not shown for clarity) in the interlayer insulating layer 14. Alternatively, to make an interconnect that connects two plugs from below, the template 21 does not contact any lines or plugs in the insulating layer 14. Thus, the template 21 may be used to form an interconnect which connects two plugs below it, or one plug below it and one plug above it, or two plugs above it, as will be described with respect to FIGS. 5A, 5B and 5C, below.

The trench 16 may be formed by lithography and etching of layer 14. This is followed by formation of the template pattern 21 in the trench 16 by deposition of a metal layer followed by patterning and etching or polishing of the metal layer. If desired, the template pattern 21 shown in FIGS. 3A and 3B may be formed by lift off, where the metal layer is deposited over a photoresist pattern followed by removal of the photoresist pattern leaving a template pattern 21 on the portions of the interlayer insulating layer 14 that was not covered by the photoresist pattern. The liftoff may be performed before or after nanotube deposition, as described below. The liftoff method may be combined with the trench forming method, such that the photoresist pattern is used as a mask to form the trench 16 in the interlayer insulating layer 14, followed by the metal layer deposition over the photoresist pattern and into the exposed trench 16, followed by the photoresist liftoff to remove the metal formed on the photoresist, to achieve the structure shown in FIG. 3B.

Alternatively, the template pattern 21 may be formed below the interlayer insulating layer 14 or inside the interlayer insulating layer (i.e., between two separately deposited portions of the insulating layer). The template pattern is then exposed in an upper surface of the interlayer insulating layer by standard lithographic masking and interlayer insulating etching methods. For example, the trench 16 may be etched in the interlayer insulating layer 16 to expose the buried template 21 to arrive at the structure shown in FIG. 3B.

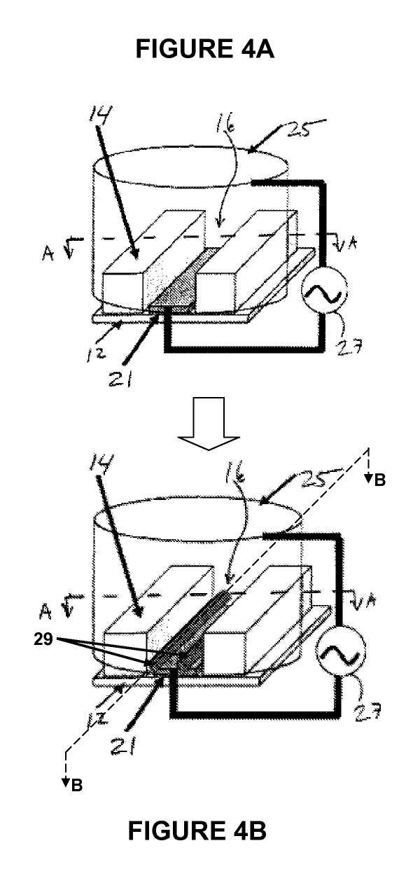

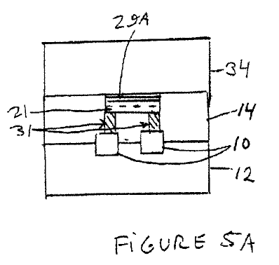

Dielectrophoresis is then used to deposit nanotubes suspended in a solvent (i.e., from a suspension) onto the metal template pattern, as shown in FIGS. 4A and 4B. The metal template pattern 21 on the substrate 12 serves as one electrode, and a separate counter electrode 23 is located in the nanotube suspension 25. By applying a DC or AC field from a voltage source 27 between the electrodes 25, 25, nanotubes 29 are deposited on the metal template pattern 21 due to the electric field gradient. The nanotubes align along the direction of the metal pattern to maximize the interaction with the surface, as shown in FIG. 4B. The sidewalls (rather than the tips) of the nanotubes contact of the template pattern 21.

Additionally, the groove or trench structure formed by the metal template pattern 21 and the trench 16 sidewalls in the interlayer insulating layer 14 will guide the nanotubes 29 to be aligned in the desired orientations, as shown in FIG. 4B. Alternatively, for metal template patterns 21 deposited on the top surface of the interlayer insulating layer 14 (as shown in FIG. 3A), photoresist or other masking material walls may be used to guide the nanotubes, as shown in FIG. 4B. The photoresist may be specially deposited to form channel sidewalls around the template pattern 21. Alternatively, the photoresist may comprise the photoresist pattern for liftoff deposition of the template pattern 21. In this case, the photoresist is lifted off after the nanotube deposition.

Controlled nanotube deposition results in formation of local horizontal interconnects on the chip. As shown in FIG. 4B, the axial directions of the carbon nanotubes in the bundle 29 are substantially aligned to an elongation direction of the conductive template 21. Thus, the template 21 is strip shaped having a length greater than the width. The nanotube axial direction is substantially aligned (i.e., at least 75% aligned) with the length direction of the template 21. Thus, the axial directions of the carbon nanotubes 29 are substantially parallel to an upper surface of the conductive template 21 (i.e., the nanotubes are oriented horizontally rather than vertically in a trench 16 in the interlayer insulating layer 14). The nanotubes comprises a horizontal interconnect for a solid state device, such as a semiconductor device.

Thus, the dielectrophoresis method may include providing the semiconductor device comprising an electrically conductive template 21 exposed in the trench 16 in the interlayer insulating layer 14 into a carbon nanotube containing solution or suspension 25, followed by applying a potential between the conductive template 21 and a counter electrode 23 located in the solution or suspension to selectively deposit the aligned nanotubes onto the conductive template 21. The nanotubes may be pre-formed into bundles 9 in the suspension 25 using the first dielectrophoresis step of the first embodiment followed by deposition onto the template 21 using the second dielectrophoresis step described above. Alternatively, the nanotubes may be deposited directly onto the template 21 from a solution or suspension 25 without first pre-forming nanotube bundles according to the second embodiment.

If desired, the substrate 12 may be lifted out of the suspension 25 directionally (i.e., sideways in the direction of template elongation) to increase the amount of nanotubes aligned horizontally. Furthermore, oxygen plasma treatment can be used to etch away nanotubes which stick out from the desired location in the trench 16.

If desired, the template 21 may be selectively removed after the step of depositing the nanotubes, by using a selective wet etching with an etching liquid which selectively etches the template material 21 compared to the nanotubes 29. Alternatively, the template 21 may be left in the completed device and may comprise a portion of the interconnect. However, since the template may have a lower conductivity than the nanotubes, preferably it is not the primary current carrier of the interconnect.

FIGS. 5A, 5B and 5C show various nanotube interconnect 29 configurations. The template 21 is shown in dashed lines to indicate that it may be removed or retained in the final device. FIG. 5A shows an interconnect 29A which contacts two metallization lines or plugs 31 in the interlayer insulating layer 14. FIG. 5B shows an interconnect 29B which contacts one metallization line or plug 31 in the interlayer insulating layer 14 and another metallization line or plug 33 in a second interlayer insulating layer 34 formed above the interconnect 29B. FIG. 5C shows an interconnect 29C which contacts two metallization lines or plugs 33 in the second interlayer insulating layer 34 formed above the interconnect 29C.

### 4. Fourth Embodiment—Formation of Vertical Interconnects

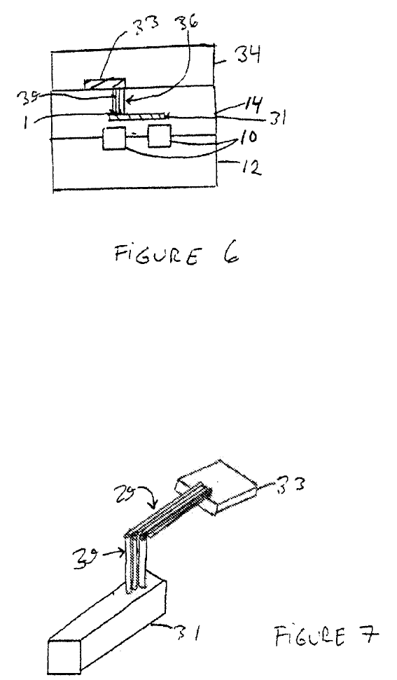

According to the fourth embodiment, the process can be used to fabricate short vertical interconnects 39 (i.e., plugs located in vias, where the combination of plug and via is sometimes simply referred to as a “via”) for a solid state device, such as a semiconductor device. Plugs connect devices vertically in a multilayer device structure. As shown in FIG. 6, one or more lithographically fabricated vertical vias 36 are formed in the interlayer insulating layer 14. A metal electrode which serves as the template 21 is located at the bottom of the via 36. The electrode 21 may comprise an underlying level of metallization exposed in the via 36 or a plug which does not fill the via 36 to the top.

By applying an electric field between the template electrode 21 and a separate counter electrode 23 in a nanotube suspension, nanotubes can be vertically deposited into the via 36 using the method of the first or second embodiment to form a vertical interconnect 39. If desired, the substrate 12 containing the template 21 may be withdrawn slowly from the suspension under the application of the field to enhance the formation of vertically aligned nanotubes in interconnect 39. Preferably, the via diameter or width (for non-cylindrical vias) is sufficiently small such that nanotubes are aligned vertically in the via (i.e., the via diameter is sufficiently small to prevent the nanotubes from lying down horizontally in the via). The nanotube axial direction is substantially aligned (i.e., at least 75% aligned) in a direction perpendicular to the plane of the top surface of the template 21. The nanotube interconnect 39 connects two metallization levels 31, 33 separated by the interlevel insulating layer 14.

In another aspect of the fourth embodiment, vertical metallic tips 1 are fabricated on the template electrode 21, and the nanotube bundles are deposited onto the metallic tips 1, similar to the method shown in FIG. 1. One or more metal tips may be formed on the electrode 21 using various lithographic etching methods, such as by forming a temporary particle mask on the electrode 21 followed by isotropic wet etching to leave sharp tips below each particle. The tips provide a mechanism to concentrate the electric field and serve as a support to hold the nanotubes in place when removing the nanotubes from the suspension. The metal tips can be left in place or etched away from the completed device.

In an alternative aspect of the fourth embodiment, instead of forming the nanotube interconnect 39 in a pre-formed via 36 in the interlayer insulating layer 14, the vertical nanotube interconnect 39 is formed on the template 21 first, followed by the formation of the interlayer insulating layer 14 around the vertical interconnect 39. This is the so-called “pillar” method of fabricating the vertical interconnect 39 which generally provides the same structure as forming the nanotube interconnect 39 in the pre-formed via 36.

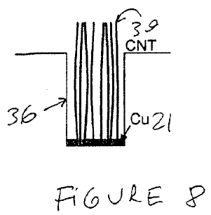

If desired, the methods of the third and fourth embodiments may be combined, as shown in FIG. 7. In this case, both horizontal 29 and vertical 39 nanotube interconnects may be formed in the same device. For example, as shown in FIG. 7, the vertical interconnect 39 may be located in a vertical via and electrically contact the horizontal interconnect 29 located in a horizontal trench. The interconnects 29, 39 contain horizontally and vertically aligned nanotubes, respectively, to electrically connect different metallization levels 31, 33. In this case, the interconnect structure is similar in shape to a dual damascene interconnect made of copper or aluminum in conventional semiconductor devices, except that it is made of nanotubes instead of metal.

### 5. Fifth Embodiment—Use of Metal Electrode as a Template

In a fifth embodiment, a metal or conductive portion of the electrode itself is used as a template 21 to form a nanotube cap portion using dielectrophoresis. In this embodiment, a metal or metal containing electrode, such as a copper, aluminum, indium, indium tin oxide, indium oxide, tin oxide, and their alloys, is used as a template. In the method of the fifth embodiment, the metal portion of an electrode, such as an interconnect, is formed over the semiconductor or other solid state device by any conventional method. The nanotubes are then deposited on the metal electrode portion by dielectrophoresis using the methods described in the previous embodiments.

In this embodiment, the electrode, such as an interconnect, is comprised of a two-portion or two layer structure. The bottom layer or portion comprises the conventional electrode, such as a copper or aluminum interconnect for a memory or logic device, or a transparent conductive electrode, such as indium tin oxide, indium oxide, etc., for a display device (such as a liquid crystal or plasma display device) or a light emitting device (such as LED, OLED, etc.). The upper layer or portion of the electrode comprises the nanotubes. This electrode may be horizontal, as described and illustrated in the third embodiment, or vertical, as described and illustrated in the fourth embodiment, or both vertical and horizontal, as illustrated in FIG. 7.

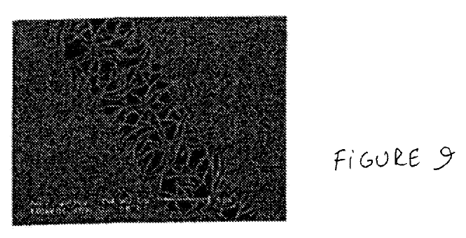

FIG. 8 illustrates an exemplary two-part vertical electrode according to the fifth embodiment. A copper interconnect portion 21 which serves as a template is located in the bottom of a vertical via 36 in the interlayer insulating layer 14. The nanotubes 39 are embedded in the copper interconnect portion 21 to form a two-part interconnect 21, 39.

A method of making the electrode 21, 39 of the fifth embodiment includes forming the copper electrode portion 21 at the bottom of the via 36. As discussed above, the electrode portion 21 may be formed in an existing via 36 or the via 36 may be formed to expose an existing electrode portion 21. Then, the nanotube bundles 39 are deposited in the via 36 by using dielectrophoresis. A post dielectrophoresis annealing step is used to embed the bottom of the nanotubes in the bundle into the copper electrode portion 21. The annealing step may be conducted at any suitable temperature and duration to embed the nanotubes.

The copper establishes a good electrical contact, reinforces the mechanical properties of the two part electrode 21, 39 and helps to align the nanotubes at the bottom of the via. Any other metals besides copper could be used in this process. Metals and metal compounds with low melting temperatures, such as aluminum or indium are preferred. As in the previous embodiments, the catalyst islands are preferably omitted from the surface of the electrode portion 21.

### 6. Sixth Embodiment—Separation of Nanotubes

In a sixth embodiment of the invention, dielectrophoresis is used to separate metallic and semiconducting nanotubes. It has been shown that metallic nanotubes and semiconducting nanotubes can be separated by controlling the dielectrophoresis process parameters (see Krupke, R.; Hennrich, F.; von Lohneysen, H.; Kappes, M. M., Separation of metallic from semiconducting single-walled carbon nanotubes, Science 301 (2003) 344-347; and Dimaki, M.; Boggild, P., Frequency dependence of the structure and electrical behavior of carbon nanotube networks assembled by dielectrophoresis, Nanotechnology 16, (6), (2005) 759-763, both incorporated herein by reference in their entirety).

For example, when the dielectric constant of the solvent is larger than that of the semiconducting carbon nanotubes but is smaller than that of metallic carbon nanotubes, then AC dielectrophoresis results in the deposition of the metallic nanotubes onto the conductive template while semiconducting nanotubes remain in the solvent. The AC frequency of the applied field is preferably in the low megahertz range, such as about 3-10 MHz, but can also range into the kilohertz and high megahertz ranges (i.e., 10 kHz to 100 MHz).

If the suspension contains bundles of mixed metallic and semiconducting nanotubes, then such mixed bundles will also be deposited on the template. Thus, in the sixth embodiment, the carbon nanotubes comprise at least 80% metallic nanotubes, such as 80% to 99% metallic SWNTs deposited on the conductive template, to account for the presence of the semiconducting nanotubes in mixed bundles in the suspension.

The use of dielectrophoresis should result in low resistance nanotube interconnects. For example, the interconnect should make an ohmic or near-ohmic contact to other electrodes. The interconnect resistivity should also be low, such as less than 20 ohms/cm², for example less than 10 ohms/cm², including 0.5 to 9 ohms/cm², for example 2 to 7 ohms/cm². Thus, in the sixth embodiment, the metallic and semiconducting nanotubes are separated during dielectrophoresis and the metallic nanotubes (and mixed bundles if present) are formed as an electrode of a device using the dielectrophoresis.

### 7. Seventh Embodiment—Conductive Network

In a seventh embodiment of the invention, rather than forming aligned nanotubes using dielectrophoresis, a network of random nanotubes forms a conductive path (i.e., interconnect) between electrodes in a semiconductor device. In this method, a nanotube containing suspension is deposited over a substrate (i.e., such as over an interlayer insulating layer) through spin coating or drop-dry (i.e., timed dry) techniques. After the solvent dries or is removed, a nanotube film remains (i.e., is controllably deposited) over a substrate. FIG. 9 shows a film of randomly oriented nanotubes. The nanotube film is then photolithographically patterned or planarized in a damascene or dual damascene process to form an interconnect comprising a conductive network of nanotubes. For example, in a damascene or dual damascene process, the nanotube network film is deposited over the top surface of the interlayer insulating layer as well as into the trench and/or via in the insulating layer, followed by a planarization step in which the film is removed from the top surface of the insulating layer, leaving the nanotube network interconnect in the trench and/or via. The nanotubes may comprise SWNTs or MWNTs.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. An integrated circuit, comprising:
a plurality of semiconductor devices located in, on or over a substrate;
an interlayer insulating layer located over the plurality of semiconductor devices; and
an electrically conductive interconnect located in the interlayer insulating layer, wherein the interconnect comprises aligned carbon nanotube bundles formed by dielectrophoresis.

43. The integrated circuit of claim 42, wherein: the carbon nanotubes comprise a primary current carrier of the interconnect; the carbon nanotubes are not interspersed with a filler material; and the carbon nanotubes are not formed on a nanotube growth catalyst island.

44. The integrated circuit of claim 42, wherein the interconnect comprises an electrically conductive template and the aligned carbon nanotubes located on the template.

45. The integrated circuit of claim 42, wherein the carbon nanotubes comprise at least 80% metallic SWNTs or MWNTs.

46. The integrated circuit of claim 42, wherein the interconnect comprises a horizontal interconnect.

47. The integrated circuit of claim 46, wherein the carbon nanotubes are aligned horizontally in a trench in the interlayer insulating layer.

48. The integrated circuit of claim 42, wherein axial directions of the carbon nanotubes are substantially aligned to an elongation direction of the conductive template.

49. The integrated circuit of claim 42, wherein the interconnect comprises a vertical interconnect.

50. The integrated circuit of claim 42, wherein the carbon nanotubes are aligned vertically in a via in the interlayer insulating layer.

51. The integrated circuit of claim 42, wherein axial directions of the carbon nanotubes are substantially perpendicular to an upper surface of the conductive template.

52. The integrated circuit of claim 42, wherein the carbon nanotubes comprise SWNTs.

53. An interconnect comprising a network of random carbon nanotubes formed by depositing a nanotube containing suspension over a substrate.

54. (canceled)

55. An integrated circuit, comprising:
a plurality of semiconductor devices located in, on or over a substrate;
an interlayer insulating layer located over the plurality of semiconductor devices; and
an electrically conductive interconnect located in the interlayer insulating layer, wherein the interconnect comprises a film of randomly oriented nanotubes.

56. The integrated circuit of claim 55, wherein the film of randomly oriented nanotubes is patterned.

57. The integrated circuit of claim 56, wherein the film of randomly oriented nanotubes is located within a trench or a via.

58. The integrated circuit of claim 57, wherein the nanotubes are not interspersed with a filler material; and the nanotubes are not formed on a nanotube growth catalyst island.

59. The integrated circuit of claim 58, wherein the nanotubes comprise at least 80% metallic nanotubes.

60. The integrated circuit of claim 59, wherein the nanotubes comprise a primary current carrier of the interconnect.

61. The integrated circuit of claim 60, wherein the interconnect is a local horizontal interconnect.

62. The integrated circuit of claim 60, wherein the interconnect is a vertical interconnect.
